(19) United States
(12) Patent Application Publication
(10) Pub. No.: US 2005/0078438 A1
(43) Pub. Date: Apr. 14, 2005

(54) Article of manufacture that attaches to computer keyboards to add storage

(76) Inventor: Dean DeVolpi, Boulder City, NV (US)

Correspondence Address: Dean DeVolpi, 603 Columbine, Lisle, IL, 60532, US

(21) Appl. No.: 10/956,464

(22) Filed: Oct. 2, 2004

Related U.S. Application Data
(60) Provisional application No. 60/510,724, filed on Oct. 10, 2003.

(51) Int. Cl. H03M 11/00

(52) U.S. Cl. 361/680; 400/717; 341/22

(57) ABSTRACT

An article of manufacture that rests under a computer keyboards to add storage with organizer base, and keyboard mating mechanism. A preferred embodiment includes the keyboard mating mechanism that pivots. A preferred embodiment includes the keyboard mating mechanism has to hold a computer keyboard.

### CROSS REFERENCE TO RELATED APPLICATIONS

This application is based on provisional application Ser. No. 60/510,724, filed on Oct. 10, 2003.

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of computers and more specifically to an article of manufacture that attaches to computer keyboards to add storage. Since the introduction of the personal computer, in addition to the typical desktop supplies such as pencils, pens, sticky notes and paper clips, items associated with the personal computer, such as diskettes, CD ROM disks and CD marking pens, are required to be readily available, and preferably close at hand to the desktop. Storage of such items upon the desktop reduces the amount of desktop space available, which is compounded by the reduction in desktop space occasioned by the placement of the computer keyboard and monitor upon the desktop.

Various desktop organizers, for holding pens, pencils, paper clips, sticky notes, rubber bands and the like have been known prior to the introduction of personal computers, and are used and directed toward the optimization of useable desktop space. Further, since the introduction of the computer, various desktop organizers and storage devices have been devised which are attached to the computer's components and are directed toward organizing supplies and optimizing usable desktop space where a computer is involved. Known desktop organizers and storage devices for use in connection with a personal computer are illustrated through the following patents of the prior art:

U.S. Pat. No. 6,681,926 to DeVolpi disclosed a keyboard with built in organizer. The present invention is a add on product to an existing keyboard which there are hundreds of millions of existing keyboards out on the market. U.S. Pat. No. 6,681,926 has the disadvantage of having to include a fully functioning computer keyboard which is the majority of the cost, this new art has a major cost advantage.

U.S. Pat. No. 5,265,735 to Hassel et al. discloses a modular organizer as a separate component, that is attached to the rear surface of a computer keyboard for storage of pens, pencils, computer disks and the like; unfortunately, the Hassel et al. device when attached to a computer keyboard as disclosed increases the overall front to rear width of the keyboard, and may not be suitable for attachment to keyboards of particular sizes or with curved rear surfaces. The Hassel et al. device does not as effectively address the prceived impression of a recently coined term by researchers at NEC-Mitsubishi “irritable desk syndrome” that can lead to illness while working at a cluttered desk. Out of sight out of mind is the optimal answer for desk top clutter.

### BRIEF SUMMARY OF THE INVENTION

The primary object of the invention is To organize the desktop.

Another object of the invention is to incease the computer users efficiency.

Another object of the invention is attaches and utilizes existing computer keyboards.

A further object of the invention is very low cost.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed an article of manufacture that attaches to computer keyboards (wired and wireless of many materials but not limited to plastic, metal, rubber) to add storage comprising of a organizer base, and can have a keyboard mating mechanism.

With hundreds of millions of keyboards being used in the USA and desk top clutter being a timeless issue the invention directly addresses this problem. This invention is low cost because it makes use of the consumers keyboard that was provided with the computer when they purchased it.

Recently NEC-Mitsubishi completed a study determining workers are getting ill with the “Irritable Desk Syndrome” because of several factors including cluttered desks. With this invention we allow for orderly removal of the clutter from the desktop area to be placed under the keyboard out of sight.

To accomplish clutter control the invention rests under or connects to or attaches to the existing keyboard on the organizer base. Methods of resting are simple gravity. Methods of connects but not limited by are be snaps, rods, pins, ties. Methods of attaching to the organizer base can be through a keyboard mating mechanism can be permanent, temporary or simply resting on it. Methods of attaching it are but not limited to as follows; permanent adhesive, temporary adhesives, putty, double sided tapes, glues, hot glues, Velcro, screws, pins, magnetic, wedging locks, press fits, snap locks, suction methods.

The keyboard mating mechanism geometry can be many surfaces to attach to a keyboard and is not limited to a flat plate, it can be a non planer resting place, it can be a insertion wedge that goes into a existing keyboard. The insertion wedge can lock or fit into a keyboard or an attachment device that locks on the keyboard to hold onto the keyboard This allows the keyboard to pivot off the organizer base to reveal the storage section of the organizer base.

Examples of pivoting mechanisms are not limited by a flexible material or a mechanical two or more piece hinge that allows pivoting.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a perspective view of the invention.

FIG. 2 is a perspective view of the invention.

FIG. 3 is a perspective view of the invention.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

In accordance with the present invention,

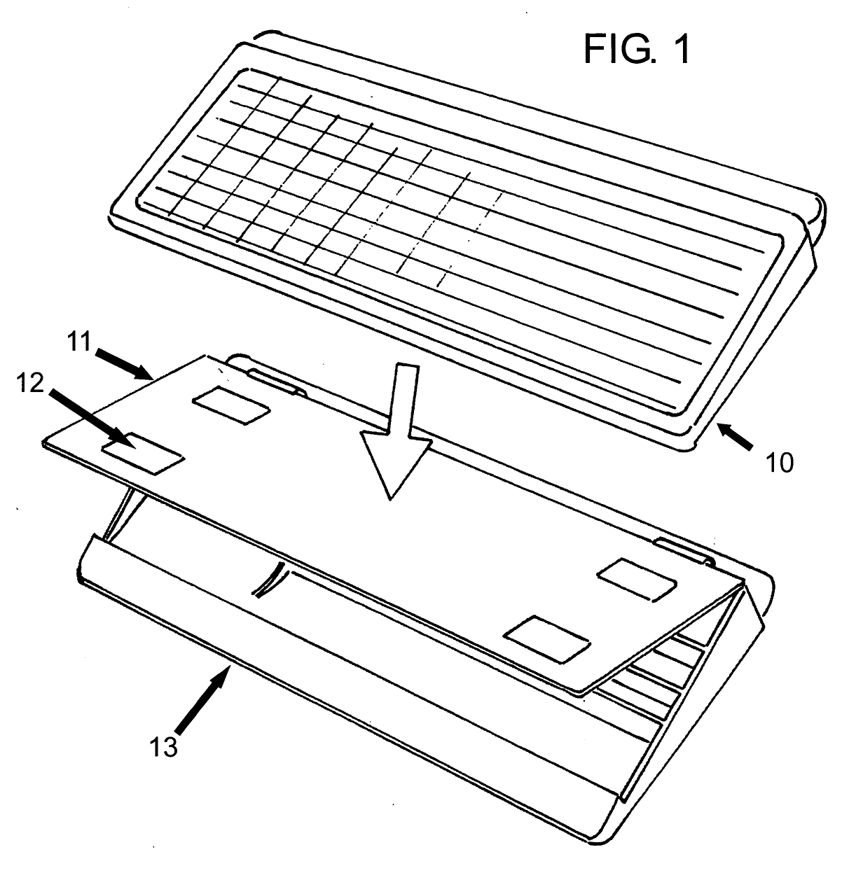

FIG. 1 shows a computer keyboard 10 that is placed on the keyboard mating mechanism 11 whereby the said keyboard mating mechanism 11 to the keyboard 10. The said keyboard mating mechanism 11 may have an attaching point 12 that maintains or adheres a connection to the organizer base 13 that allows the keyboard mating mechanism 11 to pivot to an open or closed position.

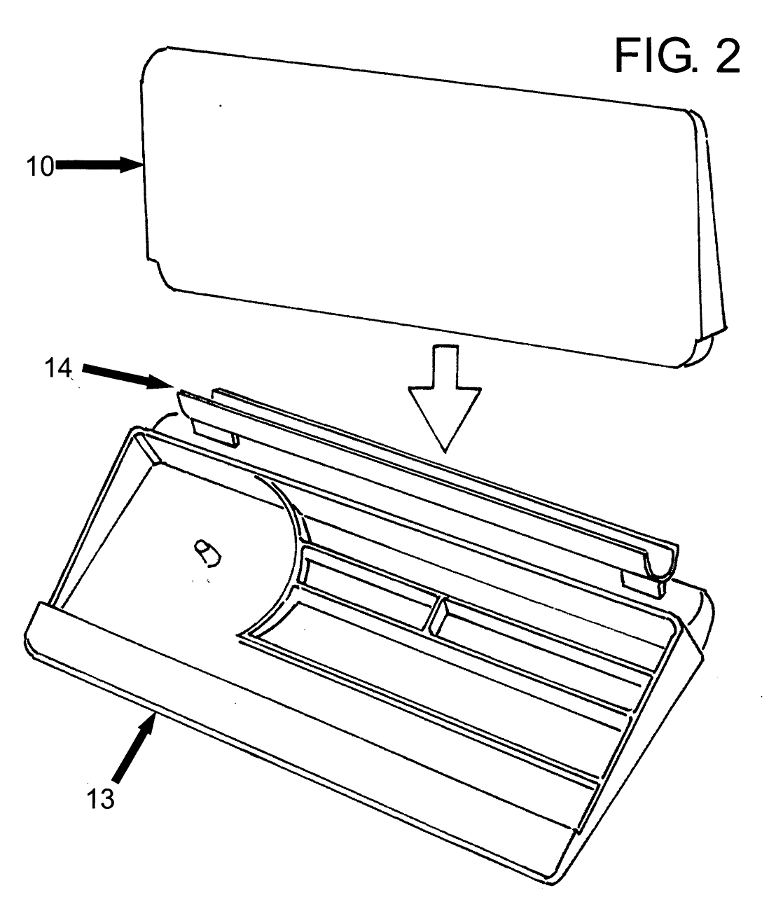

Turning to FIG. 2 shows a computer keyboard 10 that is placed in a keyboard mating mechanism 14 that holds the computer keyboard 10. The said keyboard mating mechanism 14 maintains a connection to the organizer base 13 that allows the keyboard mating mechanism 11 to pivot to an open or closed position.

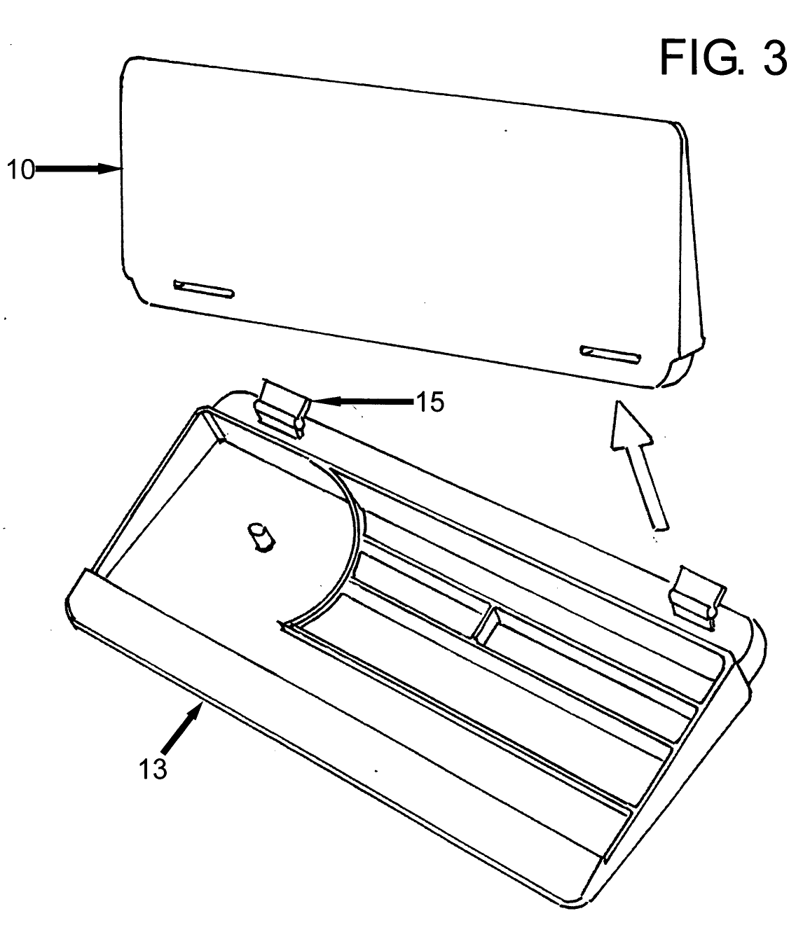

Turning to FIG. 3 shows a computer keyboard 10 that is placed into a keyboard mating mechanism 15 that holds or locks the computer keyboard 10 temporarily or permanently. The said keyboard mating mechanism 15 maintains a connection to the organizer base 13 that allows the keyboard mating mechanism to pivot to an open or closed position.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

1. An article of manufacture that rests under a computer keyboard to add storage comprising:
organizer base;

2. An article of manufacture that attaches to computer keyboards to add storage as claimed in claim 1 wherein said organizer base has a pivoting mechanism that pivots.

3. An article of manufacture that attaches to computer keyboards to add storage as claimed in claim 1 wherein said organizer base has means to hold a computer keyboard.

4. An article of manufacture that attaches to computer keyboards to add storage as claimed in claim 1 wherein said organizer base has means to lock in place a computer keyboard.

5. An article of manufacture that attaches to computer keyboards to add storage as claimed in claim 1 wherein said organizer base has means to permanently lock in place a computer keyboard.

6. An article of manufacture that attaches to computer keyboards to add storage as claimed in claim 2 wherein said organizer base has means to hold a computer keyboard.

7. An article of manufacture that attaches to computer keyboards to add storage as claimed in claim 2 wherein said organizer base has means to lock in place a computer keyboard.

8. An article of manufacture that attaches to computer keyboards to add storage as claimed in claim 2 wherein said organizer base has means to permanently lock in place a computer keyboard.

9. An article of manufacture that rests under a computer keyboard to add storage comprising:
organizer base; and
keyboard mating mechanism.

10. An article of manufacture that attaches to computer keyboards to add storage as claimed in claim 9 wherein said keyboard mating mechanism pivots.

11. An article of manufacture that attaches to computer keyboards to add storage as claimed in claim 9 wherein said keyboard mating mechanism has means to hold a computer keyboard.

12. An article of manufacture that attaches to computer keyboards to add storage as claimed in claim 9 wherein said keyboard mating mechanism has means to lock in place a computer keyboard.

13. An article of manufacture that attaches to computer keyboards to add storage as claimed in claim 9 wherein said keyboard mating mechanism has means to permanently lock in place a computer keyboard.

14. An article of manufacture that attaches to computer keyboards to add storage as claimed in claim 10 wherein said keyboard mating mechanism has means to hold a computer keyboard.

15. An article of manufacture that attaches to computer keyboards to add storage as claimed in claim 10 wherein said keyboard mating mechanism has means to lock in place a computer keyboard.

16. An article of manufacture that attaches to computer keyboards to add storage as claimed in claim 10 wherein said keyboard mating mechanism has means to permanently lock in place a computer keyboard.
